(19) United States
(12) Patent Application Publication
(10) Pub. No.: US 2025/0316456 A1
(43) Pub. Date: Oct. 9, 2025

(54) PLASMA TREATMENT DEVICE, SHOWER HEAD AND MANUFACTURING METHOD THEREFOR

(71) Applicant: ADVANCED MICRO-FABRICATION EQUIPMENT INC. CHINA, Shanghai (CN)

(72) Inventors: Zhaoyang XU, Shanghai (CN); Yongcheng ZHU, Shanghai (CN); Rubin YE, Shanghai (CN); Yijing SUN, Shanghai (CN)

(21) Appl. No.: 18/865,638

(22) PCT Filed: Jun. 27, 2023
(86) PCT No.: PCT/CN2023/102801

§ 371 Date: Nov. 13, 2024

(30) Foreign Application Priority Data
Jul. 14, 2022 (CN) 202210833158.1

(51) Int. Cl. H01J 37/32

(52) U.S. Cl. CPC H01J 37/3244; H01J 37/32495; H01J 37/32091; H01J 2237/334

(57) ABSTRACT

Provided are a shower head and a manufacturing method therefor, and a plasma treatment device. A shower head provided at the top of a vacuum reaction chamber of the plasma treatment device includes a shower head base and nozzle assemblies provided in large-diameter through holes in the shower head base, and the shower base is manufactured by spray-coating the surface of an aluminum material with an yttrium oxide coating. By additionally providing the nozzle assemblies, original micro-holes in the shower head base are changed into the large-diameter through holes for mounting the nozzle assemblies. After the large-diameter through holes are used, inner surfaces of the large-diameter through holes can be spray-coated with an anti-corrosion coating conveniently, and the anti-corrosion coating can be evenly distributed on the inner surfaces of the large-diameter through holes, so that the anti-corrosion coating is tightly bonded with the inner surfaces of the large-diameter through holes.

### TECHNICAL FIELD

The present invention relates to the field of semiconductors, in particular to a plasma treatment device, a shower head, and a manufacturing method therefor.

### BACKGROUND

The plasma treatment device includes a reaction chamber, a shower head is provided on the top of the reaction chamber to serve as an upper electrode, a base is provided inside the reaction chamber as a lower electrode, the upper electrode and the lower electrode are connected to a radio frequency source, a radio frequency field is generated between the upper electrode and the lower electrode, a reaction gas entering the reaction chamber by means of the shower head is ionized into plasma by the radio frequency field, and the plasma treats the substrate provided on the substrate base. In order to obtain a uniform distribution of the gas, many micro holes are generally provided in the shower head. Furthermore, as the shower head serving as the upper electrode needs to be accessed to radio frequency, the material of the shower head mostly uses a metal conductive material, or a semiconductor material such as monocrystalline silicon or silicon carbide. However, shower heads made of monocrystalline silicon and silicon carbide are expensive. In order to reduce the costs, a shower head is generally manufactured by fabricating micro holes in an aluminum matrix and then spray-coating an yttrium oxide coating on the aluminum matrix. Such shower heads can greatly reduce the manufacturing costs of parts. However, the yttrium oxide coating is difficult to completely cover the micro holes of the shower head. Moreover, the combination effect of the yttrium oxide coating in the micro holes and the aluminum matrix is very poor. During the plasma etching reaction, the yttrium oxide coating particles are easily detached from the micro holes, resulting in the pollution of the process.

It should be noted that the statement herein merely provides background art related to the present invention, but does not necessarily constitute prior art.

### SUMMARY

The present invention provides a plasma treatment device, a shower head thereof and a manufacturing method therefor. Anti-corrosion coatings are uniformly distributed on the surface of a shower head base. On the premise of not increasing the costs, the present invention not only ensures good process performance, but also prevents the anti-corrosion coatings from falling off, thereby reducing process pollution.

In order to achieve the described object, the present invention provides a shower head for a plasma treatment device, including:
a shower head base, having a plurality of through holes thereon;
a plurality of nozzle assemblies, each of the nozzle assemblies including a nozzle and a plug, one through hole accommodating one nozzle assembly, the nozzle being arranged in the through hole, the nozzle having a dimple, the plug being arranged in the dimple, the bottom of the nozzle having several gas outlet holes, a gas channel being formed between the nozzle and the plug, and the gas channel being in communication with the gas outlet holes.

A bottom surface of the nozzle is a cambered surface, the gas outlet holes are provided on the cambered surface, and the shape of the bottom of the plug matches that of the dimple.

The materials of the nozzles and the plugs are both ceramic materials.

The outer surface of each plug has at least one protruding portion, when the plug is placed in the dimple, the protruding portion abuts against the inner side wall of the dimple, and the gas channel is formed between the outer side wall of the plug and the inner side wall of the dimple.

The nozzles use yttrium oxide ceramics.

The plugs are made of a solid ceramic material, the outer side wall and the bottom of each plug are both provided with the protruding portion, and the gas channel is formed between the outer side wall of the plug and the inner side wall of the dimple and between the bottom of the plug and the bottom of the dimple.

The inner wall of the dimple is provided with connecting grooves, the number of the connecting grooves is equal to the number of the protruding portions provided on the outer side wall of the plugs, the connecting grooves are provided at positions corresponding to that of the protruding portions provided on the outer side wall of the plugs, the depth of the connecting grooves is less than the protruding height of the protruding portions on the outer side wall of the plugs.

Each of the connecting grooves includes a through groove and a clamping groove in communication with each other, one end of the through groove is closed, and the other end extends to the top of the dimple, both ends of the clamping groove are closed ends, and the length of the clamping groove matches the length of the protruding portion provided on the outer side wall of the plug.

The plugs are made of a porous ceramic material, the bottom of each plug is provided with the protruding portion, the bottom of the plug and the bottom of the dimple form the gas channel, the outer side wall of the plug is adhered to the inner side wall of the dimple, and voids in the porous ceramic material are in communication with the gas channel.

The gas outlet holes are symmetrically distributed evenly at the cambered surface bottom of the nozzles.

The inner diameter of the through holes is greater than 10 mm.

The shower head base is made of an aluminum material, and the surface of the aluminum material is spray-coated with an anti-corrosion coating.

The material of the anti-corrosion coating includes yttrium oxide.

The diameter of the gas outlet holes is 0.3 mm to 2 mm.

The outer diameter of the nozzles is equal to the inner diameter of the through holes.

The width of the gas channels is 0.1 mm to 0.3 mm.

A seal ring is provided between the nozzle and the shower head base.

The present invention further provides a method for manufacturing a shower head, including the following steps:
using an aluminium material to fabricate a shower head base, fabricating a plurality of through holes in the shower head base, and spray-coating all surfaces of the shower head base with an yttrium oxide coating;
using a ceramic material to fabricate nozzles and plugs, and assembling the nozzles and the plugs into nozzle assemblies;
and mounting each of the nozzle assemblies into the through holes in the shower head base.

The present invention further provides a plasma treatment device, including a vacuum reaction chamber, in which a base for supporting a substrate is provided in the vacuum reaction chamber, a shower head is further provided in the vacuum reaction chamber, and the shower head is connected to a gas source by means of a mounting base.

The mounting base is connected to a shower head base, a gap is formed between the mounting base and the plug, and both ends of the gap are in communication with the gas source and the gas channel, respectively.

The plasma treatment device is a capacitively coupled plasma etching device.

Compared with the prior art, the technical solution of the present invention has the following beneficial effects:

The present invention provides a shower head and a manufacturing method therefor. The shower head base is manufactured by spray-coating/depositing an yttrium oxide coating on the surface of an aluminum alloy. By adding the gas nozzle assemblies and mounting same on the large-diameter through holes of the shower head base, the micro-hole features of a traditional shower head are avoided. The use of a shower head base with large-diameter through holes can facilitate spray-coating/deposition of an anti-corrosion coating in the diameter thereof, and can enable the anti-corrosion coating to be uniformly distributed on the inner surface of the large-diameter through holes, so that the anti-corrosion coating is tightly attached to the inner surface of the large-diameter through holes. The novel shower head not only ensures the good process performance, but also avoids the problem that the anti-corrosion coating in the micro holes is easy to fall off, thereby reducing the process pollution.

### BRIEF DESCRIPTION OF THE DRAWINGS

FIG. 1 is a schematic structural view of a capacitively coupled plasma etching device according to an example of the present invention.

FIG. 2 is a side sectional view of the shower head shown in FIG. 1.

FIG. 3 is a top view of the shower head shown in FIG. 2.

FIG. 4 is a bottom view of the shower head shown in FIG. 2.

FIG. 5 is a schematic view of a nozzle shown in FIG. 2.

FIG. 6 is a top view of a shower head according to an example of the present invention.

FIG. 7 is a sectional view along the C-C plane in FIG. 6.

FIG. 8 is a schematic diagram of a plug shown in FIG. 6.

FIG. 9 is a schematic view of a nozzle shown in FIG. 6.

FIG. 10 is a top view of a shower head according to another example of the present invention.

FIG. 11 is a sectional view along the D-D plane in FIG. 10.

FIG. 12 is a schematic view of a plug shown in FIG. 10.

### BEST IMPLEMENTATION FOR THE PRESENT INVENTION

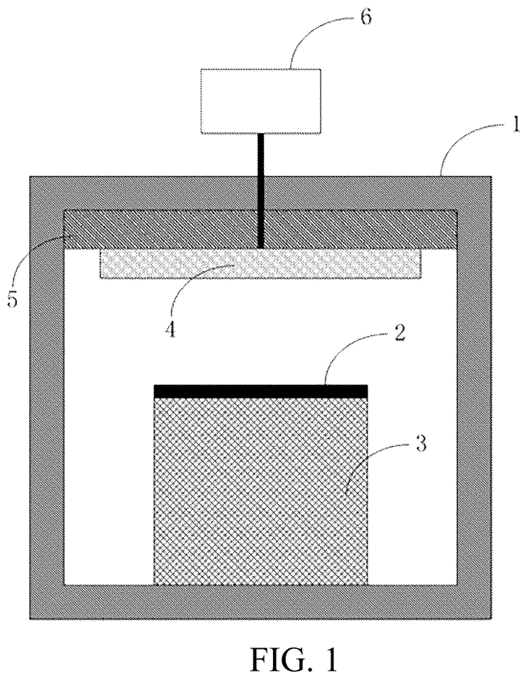

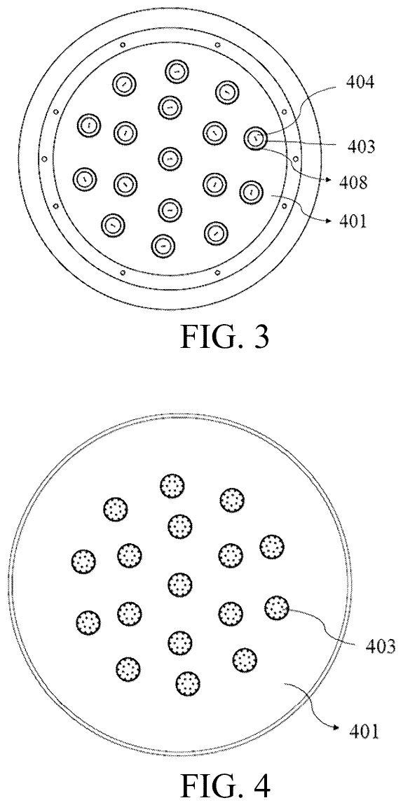

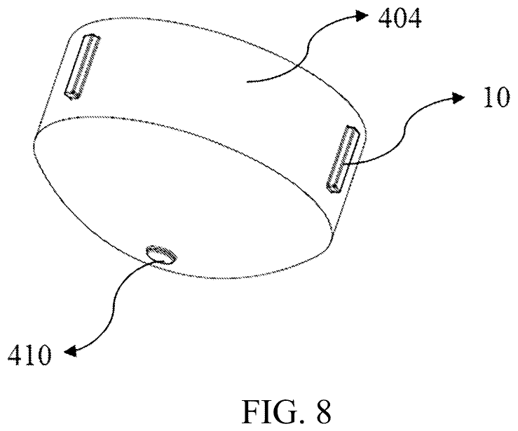

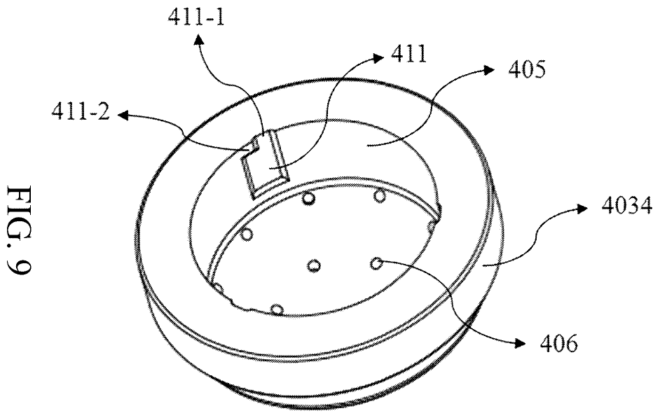

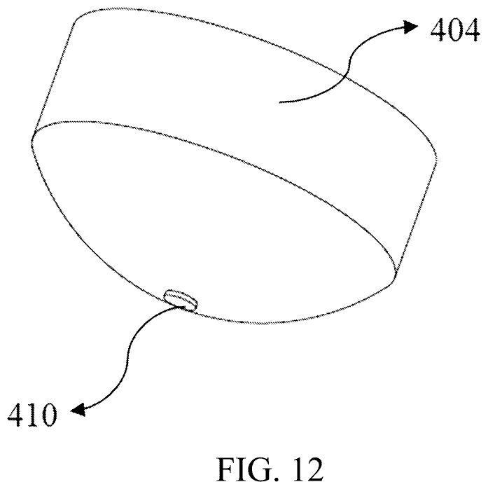

The preferred examples of the present invention are described in detail with reference to FIGS. 1-12.

As shown in FIG. 1, the present invention provides a capacitively coupled plasma etching device, including a vacuum reaction chamber 1, in which a base 3 for supporting a substrate 2 is provided in the vacuum reaction chamber 1, a shower head 4 is further provided at the top of the vacuum reaction chamber 1, and the shower head 4 is connected to a gas source 6 by means of a mounting base 5.

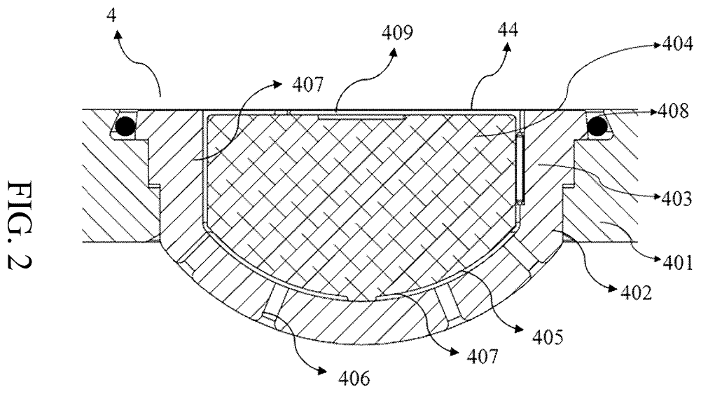

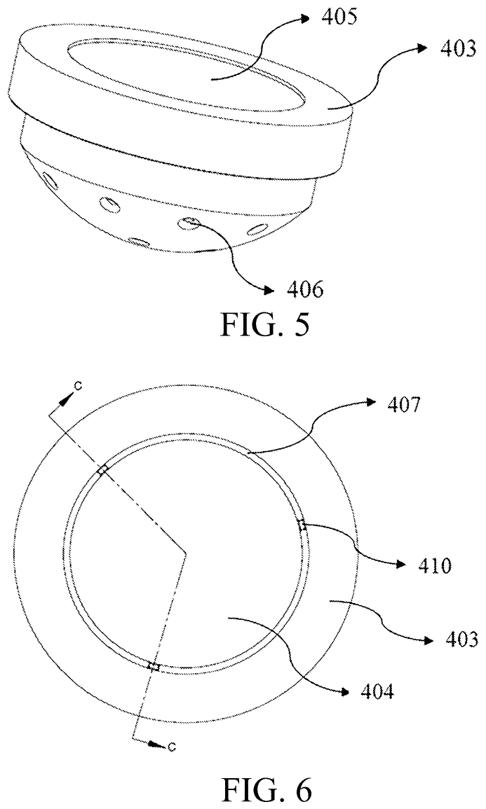

As shown in FIGS. 2 to 5, the shower head 4 includes a shower head base 401 connected to the mounting base 5, the shower head base 401 is made of an aluminum material, the shower head base 401 has a plurality of through holes 402, the surface of the aluminum material of the shower head base 401 (including the inner surface of the through holes 402) is entirely coated with an anti-corrosion coating, for example, an yttrium oxide coating, and the inner diameter of the through holes 402 is greater than 10 mm so as to spray-coat an anti-corrosion coating on the inner surface of the through holes 402; furthermore, the anti-corrosion coating is evenly distributed on the inner surface of the through holes 402, so that the anti-corrosion coating is tightly attached to the inner surface of the through holes 402, thereby avoiding the problem of the pollution due to detachment of the anti-corrosion coating. Each of the through holes 402 in the shower head base 401 accommodates a nozzle assembly 44, the nozzle assembly 44 includes a nozzle 403 and a plug 404 provided in the nozzle 403, the nozzle 403 is placed in the through hole 402, the outer diameter of the nozzle 403 is equal to the inner diameter of the through hole 402, and a rubber seal ring 408 is provided between the nozzle 403 and the shower head base 401; and on the one hand, the rubber seal ring 408 can ensure that the reaction gas is sprayed out of the nozzle 403 without overflowing out of the through hole 402, on the other hand, the compressed rubber seal ring 408 can press the nozzle 403, so that the nozzle 403 is fixed on the shower head base 401. The nozzle 403 has a dimple 405, the plug 404 is arranged in the dimple 405, a gas channel 407 is formed between the plug 404 and the nozzle 403, a plurality of gas outlet holes 406 are formed at the bottom of the nozzle 403, and the gas channel 407 is in communication with the gas outlet holes 406. A gap 409 is provided between the plug 404 and the mounting base 5, and two ends of the gap 409 are respectively in communication with a gas source 6 and the gas channel 407, so as to introduce a reaction gas from the gas source 6 into the gas channel 407 in the shower head through the gap 409, and finally, the reaction gas is released into the vacuum reaction chamber 1 through the gas outlet holes 406 in communication with the gas channel 407. The bottom surface of the nozzles 403 is provided as a cambered surface, the gas outlet holes 406 are provided on the cambered surface (as shown in FIG. 5), the gas outlet holes 406 are symmetrically and evenly distributed on the cambered surface bottom of the nozzles 403, and the gas outlet holes 406 are provided on the cambered surface, so that the reaction gas released by the gas outlet holes 406 can be more evenly distributed all around, improving the uniformity of the gas distribution in the vacuum reaction chamber. The diameter range of the gas outlet holes 406 is 0.3 mm to 2 mm, and preferably 0.5 mm. The gas outlet holes 406 serve as micro holes having a relatively small diameter, so that the reaction gas emitted from the gas outlet holes 406 can be controlled, thereby ensuring the uniformity of the release of the reaction gas. The shape of the bottom of the plug 404 match the shape of the dimple 405 in the nozzle 403, so that a gas channel 407 having a uniform width is formed between the plug 404 and the nozzle 403. If the gap between the plug 404 and the nozzle 403 is too large, a plasma arc is easily generated, which may cause damage to the structure of the device; therefore, the width of the gas channel 407 formed between the plug 404 and the nozzle 403 needs to be controlled. Generally, the width of the gas channel 407 is set to be from 0.1 mm to 0.3 mm, and in this narrower width range, plasma arc generation between the plug 404 and the nozzle 403 can be avoided. The nozzle 403 and the plug 404 are both made of a ceramic material, and the nozzle 403 is mostly made of yttrium oxide ceramics. The wall thickness of the nozzle 403 is generally fabricated to be 1 mm to 5 mm. The nozzle 403 with such a wall thickness is easy to fabricate, and on the premise of satisfying the stiffness, the nozzle 403 with a smaller wall thickness uses the less material, thereby saving the costs.

In the present invention, by adding the nozzle assemblies, original micro holes in the shower head base are changed into large-diameter through holes for mounting the nozzle assemblies, and after using the large-diameter through holes, it is convenient to spray-coat an anti-corrosion coating on the inner surface of the large-diameter through holes, and the anti-corrosion coating can be evenly distributed on the inner surface of the large-diameter through holes, the anti-corrosion coating is tightly attached to the inner surface of the large-diameter through holes, thereby preventing the anti-corrosion coating in the through holes from falling off, and reducing the particles pollution.

The plug 404 can uses different ceramic materials according to the requirements of the process environment, for example, using a solid ceramic material, and further for example, using a porous ceramic material, so as to form a gas path by using voids of the porous ceramic material itself.

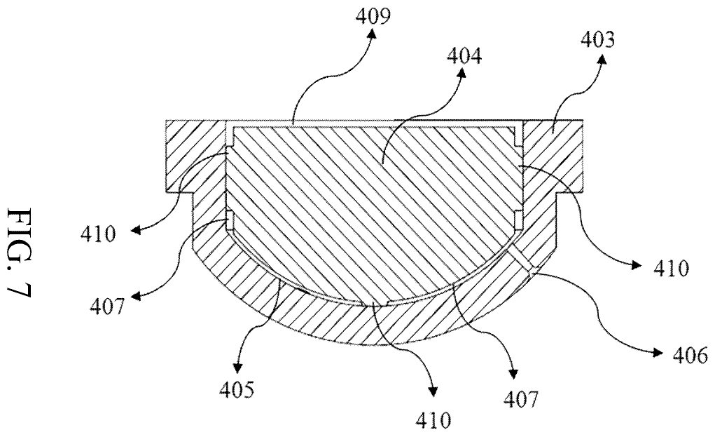

As shown in FIGS. 6 to 9, in an example of the present invention, the plug 404 is made of a solid ceramic material, such as alumina, yttrium oxide, or aluminum nitride. The anti-plasma corrosion material can be used to manufacture the plug 404. Protruding portions 410 are provided on both the outer side wall and the bottom of the plug 404. For example, two protruding portions 410 may be symmetrically provided on the outer side wall of the plug 404, or three protruding portions 410 may be evenly spaced apart from one another, and one protruding portion 410 is provided right at the center of the bottom of the plug. Correspondingly, the inner side wall of the dimple 405 of the nozzle 403 is provided with a connecting groove 411, the number of the connecting grooves 411 is the same as the number of the protruding portions 410 provided on the outer side wall of the plugs 404, and the arrangement positions of the connecting grooves 411 correspond to that of the protruding portions 410 provided on the outer side wall of the plugs 404. Each of the connecting grooves 411 includes a through groove 411-1 and a clamping groove 411-2 in communication with each other, one end of the through groove 411-1 is closed, and the other end extends to the top of the dimple 405, both ends of the clamping groove 411-2 are closed ends, and the length of the clamping groove 411-2 matches the length of the protruding portion 410 provided on the outer side wall of the plug 404. When the plug 404 is placed in the dimple 405 of the nozzle 403, the protruding portion 410 on the outer side wall of the plug 404 slides into the connecting groove 411 from the through groove 411-1 on the inner side wall of the dimple 405, and then the plug 404 is rotated so that the protruding portion 410 on the outer side wall of the plug 404 falls into the clamping groove 411-2. In this case, the plug 404 is reliably connected to the nozzle 403. The height of the protrusion of the protruding portion 410 on the outer side wall of the plug 404 should be greater than the depth of the connecting groove 411, so that the gas channel 407 is formed between the outer side wall of the plug 404 and the inner side wall of the dimple 405 and between the bottom of the plug 404 and the bottom of the dimple 405. The protruding portion 410 causes a gas channel 407 to be formed between the plug 404 and the nozzle 403 so as to prevent the nozzle 403 from directly contacting the plug 404 and creating a partial blockage.

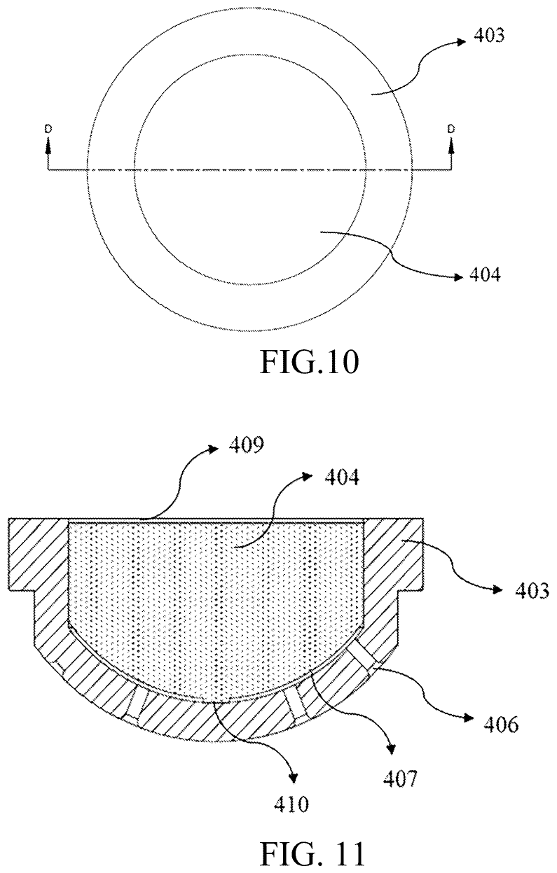

As shown in FIGS. 10 to 12, in another example of the present invention, the plug 404 is made of a porous ceramic material, such as aluminum nitride, silicon carbide, and aluminum oxide. Because the plug 404 is made of a porous ceramic material, naturally, there are voids in the plug 404 can serve as an internal gas channel, therefore, in the present example, the protruding portion 410 provided at the outer side wall of the plug 404 may be omitted, and the protruding portion 410 may be merely provided at the bottom of the plug 404, one end of an internal gas channel naturally existing in the plug 404 is connected to a gap 409 between same and the mounting base 5, the other end thereof is in communication with a gas channel 407 formed between the bottom of the plug 404 and the bottom of the dimple 405, then accordingly, the outer side wall of the plug 404 can be directly attached to the inner side wall of the protruding portion 405, and thus the gas channel 407 formed between the outer side wall of the plug 404 and the inner side wall of the dimple 405 is omitted, so that the difficulty in fabricating the plug 404 can be reduced, and the fabricating time of the plug 404 can be reduced.

The present invention provides a shower head, a shower head base is still manufactured by spray-coating an yttrium oxide coating on the surface of an aluminum material, by adding the nozzle assemblies, original micro holes on the shower head base are changed into large-diameter through holes for mounting the nozzle assemblies, and after using the large-diameter through holes, it is convenient to spray-coat an anti-corrosion coating on the inner surface of the large-diameter through holes, and the anti-corrosion coating can be evenly distributed on the inner surface of the large-diameter through holes, so that the anti-corrosion coating is tightly attached to the inner surface of the large-diameter through holes. The novel shower head not only ensures the good process performance without increasing the costs, but also prevents the anti-corrosion coating in the through holes from falling off, thereby reducing the process pollution.

The present invention further provides a method for manufacturing a shower head, including first using an aluminum material to fabricate a shower head base; then fabricating a plurality of through holes on the shower head base, in which the inner diameter size of the through holes is greater than 10 mm, and the diameter of the through holes is larger so as to facilitate spray-coating of an anti-corrosion coating on the inner surface of the through holes; after all the through holes are fabricated, spray-coating an yttrium oxide coating on all the surfaces of the shower base, so that the anti-corrosion coating is uniformly distributed on the inner surfaces of the large-diameter through holes, and the anti-corrosion coating is tightly attached to the inner surfaces of the large-diameter through holes. While manufacturing a shower head base, nozzle assemblies can be manufactured synchronously, nozzles and plugs are formed by sintering yttrium oxide ceramics and performing machining, and the plugs are fitted into and assembled with the nozzles to form the nozzle assemblies. Finally, each nozzle assembly is mounted into the through holes on the shower head base, and rubber seal rings are provided between the nozzles and the shower head base, thereby completing the manufacture of the whole shower head.

The present invention provides a shower head and a manufacturing method therefor. The shower head base is manufactured by spray-coating/depositing an yttrium oxide coating on the surface of an aluminum alloy. By adding the gas nozzle assemblies and mounting same on the large-diameter through holes of the shower head base, the micro-hole features of a traditional shower head are avoided. The use of a shower head base with large-diameter through holes can facilitate spray-coating/deposition of an anti-corrosion coating in the diameter thereof, and can enable the anti-corrosion coating to be uniformly distributed on the inner surface of the large-diameter through holes, so that the anti-corrosion coating is tightly attached to the inner surface of the large-diameter through holes. The novel shower head not only ensures the good process performance, but also avoids the problem that the anti-corrosion coating in the micro holes is easy to fall off, thereby reducing the process pollution.

It should be noted that, in the examples of the present invention, the orientation or position relations indicated by the terms such as “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, and “circumferential” are the orientation or position relations based on the accompanying drawings, which are merely for convenience in describing the examples, rather than indicating or implying that the indicated apparatus or element must have a particular orientation, be constructed and operated in a particular orientation, and thus cannot be understood as limits to the present invention. In addition, the terms “first”, “second”, and “third” are used for descriptive purposes only and are not to be construed as indicating or implying a relative importance.

In the present invention, unless specified or defined otherwise, the terms such as “mount”, “connect”, “connected” and “fix” should be understood broadly, for example, “connect” may be fixed connection, detachable connection, or integral connection, may also be mechanical or electrical connection, may also be direct connection or indirect connection by means of an intermediate medium, and may also be inner communications of two elements or interaction relationships between two elements. A person of ordinary skill in the art may understand the specific meanings of the described terms in the present invention according to specific situations.

Although the contents of the present invention are described in detail with reference to the preferred embodiments above, it should be understood that the description above should not be taken as limiting. Various modifications and alternatives to the present invention will become apparent to those skilled in the art upon reading the foregoing disclosure. Accordingly, the protection scope of the present invention shall be limited by the appended claims.

1. A shower head for a plasma treatment device, comprising:
a shower head base, having a plurality of through holes thereon;
a plurality of nozzle assemblies, each of the nozzle assemblies comprising a nozzle and a plug, one through hole accommodating one nozzle assembly, the nozzle being arranged in the through hole, the nozzle having a dimple, the plug being arranged in the dimple, the bottom of the nozzle having several gas outlet holes, a gas channel being formed between the nozzle and the plug, and the gas channel being in communication with the gas outlet holes.

2. The shower head according to claim 1, wherein a bottom surface of the nozzle is a cambered surface, the gas outlet holes are formed in the cambered surface, and the shape of the bottom of the plug matches that of the dimple.

3. The shower head according to claim 2, wherein the materials of the nozzles and the plugs are both made of ceramic materials.

4. The shower head according to claim 3, wherein the outer surface of each plug has at least one protruding portion, when the plug is placed in the dimple, the protruding portion abuts against the inner side wall of the dimple, and the gas channel is formed between the outer side wall of the plug and the inner side wall of the dimple.

5. The shower head according to claim 3, wherein the nozzle uses yttrium oxide ceramics.

6. The shower head according to claim 4, wherein the plug is made of a solid ceramic material, the outer side wall and the bottom of the plug are both provided with protruding portions, and the gas channel is formed between the outer side wall of the plug and the inner side wall of the dimple and between the bottom of the plug and the bottom of the dimple.

7. The shower head according to claim 6, wherein the inner wall of the dimple is provided with connecting grooves, the number of the connecting grooves is equal to the number of the protruding portions provided on the outer side wall of the plug, the connecting grooves are provided at positions corresponding to that of the protruding portions provided on the outer side wall of the plug, the depth of the connecting grooves is less than the protruding height of the protruding portions on the outer side wall of the plug.

8. The shower head according to claim 7, wherein each of the connecting grooves comprises a through groove and a clamping groove in communication with each other, one end of the through groove is closed, and the other end extends to the top of the dimple, both ends of the clamping groove are closed ends, and the length of the clamping groove matches the length of the protruding portion provided on the outer side wall of the plug.

9. The shower head according to claim 4, wherein the plug is made of a porous ceramic material, the bottom of each plug is provided with the protruding portion, the bottom of the plug and the bottom of the dimple form the gas channel, the outer side wall of the plug is attached to the inner side wall of the dimple, and voids in the porous ceramic material are in communication with the gas channel.

10. The shower head according to claim 2, wherein the gas outlet holes are symmetrically distributed evenly at the cambered surface bottom of the nozzle.

11. The shower head according to claim 1, wherein the inner diameter of the through holes is greater than 10 mm.

12. The shower head according to claim 1, wherein the shower head base is made of an aluminum material, and the surface of the aluminum material is spray-coated with an anti-corrosion coating.

13. The shower head according to claim 12, wherein the material of the anti-corrosion coating comprises yttrium oxide.

14. The shower head according to claim 1, wherein the diameter of the gas outlet holes is 0.3 mm to 2 mm.

15. The shower head according to claim 1, wherein the outer diameter of the nozzle is equal to the inner diameter of the through holes.

16. The shower head according to claim 1, wherein the width of the gas channel is 0.1 mm to 0.3 mm.

17. The shower head according to claim 1, wherein a seal ring is provided between the nozzle and the shower head base.

18. A method for manufacturing the shower head according to claim 1, comprising the following steps:
using an aluminium material to fabricate a shower head base, fabricating a plurality of through holes in the shower head base, and spray-coating all surfaces of the shower head base with an yttrium oxide coating;
using a ceramic material to fabricate nozzles and plugs, and assembling the nozzles and the plugs into nozzle assemblies;
and mounting each of the nozzle assemblies into the through holes in the shower head base.

19. A plasma treatment device, comprising a vacuum reaction chamber, wherein a base for supporting a substrate is provided in the vacuum reaction chamber, the shower head according to claim 1, is further provided in the vacuum reaction chamber, and the shower head is connected to a gas source by means of a mounting base.

20. The plasma treatment device according to claim 19, wherein the mounting base is connected to a shower head base, a gap is formed between the mounting base and the plug, and both ends of the gap are in communication with the gas source and the gas channel, respectively.

21. The plasma treatment device according to claim 19, wherein the plasma treatment device is a capacitively coupled plasma etching device.
